(19) United States
(12) Patent Application Publication
(10) Pub. No.: US 2023/0092151 A1
(43) Pub. Date: Mar. 23, 2023

(54) SEMICONDUCTOR INTEGRATED CIRCUIT, ELECTRONIC DEVICE, AND FREQUENCY DETECTING METHOD

(71) Applicant: KIOXIA CORPORATION, Tokyo (JP)

(72) Inventor: Go URAKAWA, Yokohama Kanagawa (JP)

(21) Appl. No.: 17/680,105

(22) Filed: Feb. 24, 2022

(30) Foreign Application Priority Data
Sep. 22, 2021 (JP) 2021-154522

(51) Int. Cl. H03L 7/099; H03L 7/095; H03L 7/113

(52) U.S. Cl. CPC H03L 7/099; H03L 7/095; H03L 7/113

(57) ABSTRACT

A semiconductor integrated circuit includes a calibration control circuit configured to generate a setting value for a frequency of a first clock signal, based on a frequency of a second clock signal and a frequency of a third clock signal obtained by dividing the first clock signal by a first frequency division ratio, a phase-locked loop configured to generate a control voltage signal based on a difference in phase between the second and third clock signals, and generate the first clock signal based on the generated control voltage and the setting value, and a determination control circuit configured to determine whether the first and second clock signals are in a locked state, and update the first frequency division ratio based on whether the first and second clock signals are in the locked state.

### CROSS-REFERENCE TO RELATED APPLICATION(S)

This application is based upon and claims the benefit of priority from Japanese Patent Application No. 2021-154522, filed Sep. 22, 2021, the entire contents of which are incorporated herein by reference.

### FIELD

Embodiments described herein relate generally to a semiconductor integrated circuit, an electronic device, and a frequency detecting method performed by a semiconductor integrated circuit or an electronic device.

### BACKGROUND

An electronic device uses internal clock signals to operate internal circuits. The internal clock signal is generated by reference to a reference clock signal. When an electronic device is connected to a known host device, the electronic device receives a reference clock signal having a known frequency from the host device. The electronic device that has received such a reference clock signal can generate an internal clock signal based on the received reference clock signal. However, when the electronic device is connected to an unknown host device, the frequency of the reference clock signal may be unknown. This may disrupt the generation of the internal clock signal by the electronic device.

### BRIEF DESCRIPTION OF THE DRAWINGS

FIG. 1 shows a block diagram of an electric device according to an embodiment.

FIG. 2 shows a block diagram of a semiconductor integrated circuit according to an embodiment.

FIG. 3 shows a block diagram of a calibration circuit in a semiconductor integrated circuit according to an embodiment.

FIG. 4 depicts an operation of a calibration circuit in a semiconductor integrated circuit according to an embodiment.

FIG. 5 shows a correspondence table of a reference clock signal in a semiconductor integrated circuit according to an embodiment.

FIG. 6 shows a flowchart of an operation of a semiconductor integrated circuit according to an embodiment.

FIG. 7 depicts the principle of a frequency detection according to an embodiment.

FIG. 8 depicts the principle of a frequency detection according to an embodiment.

FIG. 9 depicts a determination of a calibration code according to an embodiment.

### DETAILED DESCRIPTION

Embodiments provide a semiconductor integrated circuit, an electronic device, and a frequency detecting method. In the embodiments, a frequency of a clock signal can be detected without increasing the required circuit size.

In general, according to one embodiment, a semiconductor integrated circuit includes a calibration control circuit configured to generate a setting value for a frequency of a first clock signal, based on a frequency of a second clock signal from an external device and a frequency of a third clock signal that is obtained by dividing the first clock signal by a first frequency division ratio. The semiconductor integrated circuit further includes a phase-locked loop configured to generate a control voltage signal based on a difference in phase between the second and third clock signals, and generate the first clock signal based on the generated control voltage and the setting value. The semiconductor integrated circuit further includes a determination control circuit configured to determine whether the first and second clock signals are in a locked state, and update the first frequency division ratio based on whether the first and second clock signals are in the locked state.

(Electronic Device)

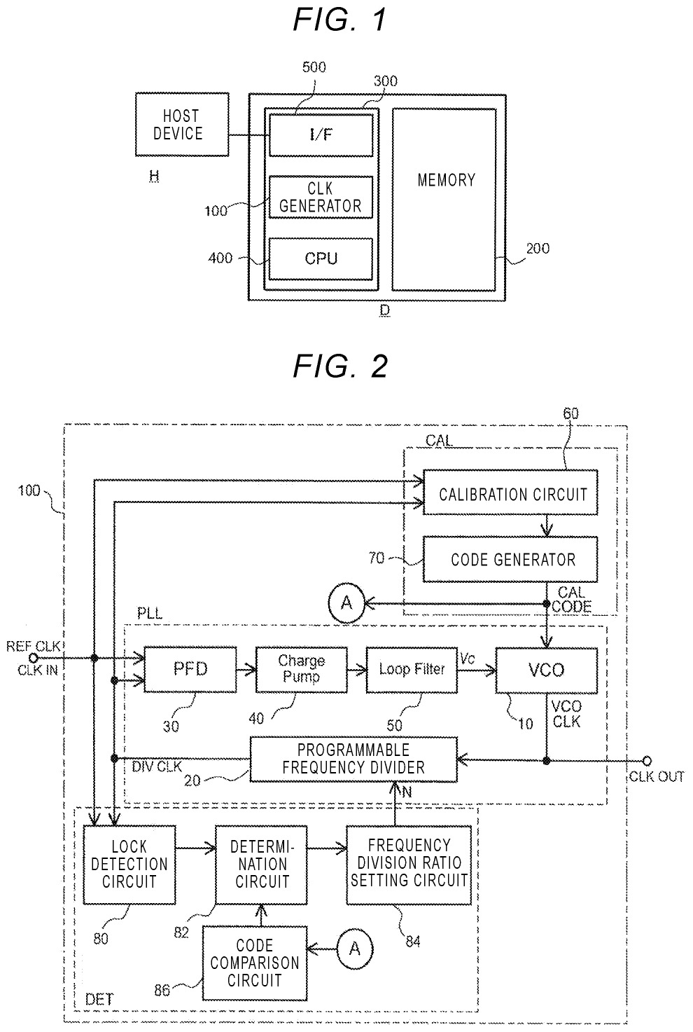

Hereinafter, embodiments of the present disclosure will be described with reference to the accompanying drawings. As illustrated in FIG. 1, an electronic device D of an embodiment is connected to a host device H. The electronic device D includes a memory 200 and a controller 300. The controller 300 includes a clock (CLK) generator 100, a central processing unit (CPU) 400, and an interface circuit (I/F) 500. The controller 300 performs, for example, data writing to the memory 200 and data reading from the memory 200 in accordance with a command from the host device H. The controller 300 is configured as a system on a chip (SoC) including the clock generator 100, the CPU 400, and the interface circuit 500 in one package.

The clock generator 100 can be a semiconductor integrated circuit that supplies a clock signal to each circuit component (e.g., the interface circuit 500) in the electronic device D. The clock generator 100 receives a clock signal from outside of the electronic device D, such as the host device H or the like. The clock generator 100 generates a clock signal or clock signals to be used by each circuit component provided in the electronic device D, based on the received clock signal. Generated clock signals may be a single frequency or different frequencies for different circuit components.

The memory 200 is, for example, a storage device capable of storing information in a nonvolatile manner. The memory 200 is implemented as, for example, a NAND type flash memory. The memory 200 stores, for example, user data transmitted from the host device H, management information of the electronic device D, system data, and log data of the host device H and the electronic device D.

The CPU 400 is an arithmetic circuit that performs various controls by executing programs or firmware read from a storage device such as the memory 200 or a ROM.

The interface circuit 500 transmits and receives signals to and from the host device H. Based on a clock signal generated by the clock generator 100, the interface circuit 500 processes the transfer of signals between the electronic device D and the host device H.

The clock generator 100 generates a clock signal synchronized with the clock signal used by the host device H. Thus, the clock generator 100 may receive a reference clock signal from the host device H for the purposes of synchronization or the like. However, when the electronic device D is initially connected to an unknown host device H, the frequency of the reference clock signal received from the host device H may be unknown. Thus, the clock generator 100 has a function of detecting the frequency of the reference clock signal being received from the host device H.

(Configuration of Clock Generator)

The configuration of the clock generator 100 according to an embodiment will be described with reference to FIG. 2. As illustrated in FIG. 2, the clock generator 100 includes a phase-locked loop PLL, a calibration control circuit CAL, and a determination control circuit DET. The clock generator 100 receives a reference clock signal REF CLK as an input signal and outputs an oscillation clock signal VCO CLK. The reference clock signal REF CLK is from outside of the clock generator 100 and input via a node CLK IN. The reference clock signal REF CLK is transmitted from, for example, the host device H. The oscillation clock signal VCO CLK is output to outside of the clock generator 100 via a node CLK OUT. The oscillation clock signal VCO CLK is used by each circuit component provided in the electronic device D of this example. The clock generator 100 also has a function of a frequency detector.

The phase-locked loop PLL is an oscillation circuit block that generates the oscillation clock signal VCO CLK based on the reference clock signal REF CLK. The phase-locked loop PLL receives the reference clock signal REF CLK, and then generates the oscillation clock signal VCO CLK and a frequency-divided clock signal DIV CLK based on the reference clock signal REF CLK. The phase-locked loop PLL includes a voltage-controlled oscillator (VCO) 10, a programmable frequency divider 20 that functions as a feedback frequency divider, a phase frequency detector (PFD) 30, a charge pump 40, and a loop filter 50.

The voltage-controlled oscillator 10 is an oscillator for which an oscillation frequency can be controlled based on a provided control voltage Vc. The voltage-controlled oscillator 10 generates the oscillation clock signal VCO CLK, which has an oscillation frequency that is controlled/adjusted according to at least in part by the control voltage Vc. The voltage-controlled oscillator 10 can also receive a calibration code (“CAL CODE”) and change the base oscillation frequency of the VCO 10, so as to change the relationship between the control voltage Vc and the oscillation frequency “f” (of oscillation clock signal VCO CLK). That is, the voltage-controlled oscillator 10 may generate the oscillation clock signal VCO CLK based on both value/level of the control voltage Vc and the received calibration code (“CAL CODE”). The voltage-controlled oscillator 10 may be, for example, an oscillation system using the LC (inductance-capacitance) resonance.

The programmable frequency divider 20 is a circuit that feeds back a frequency-divided clock signal DIV CLK to the phase frequency detector 30. The frequency-divided clock signal DIV CLK is obtained by dividing the oscillation clock signal VCO CLK output by the voltage-controlled oscillator 10. The programmable frequency divider 20 receives the oscillation clock signal VCO CLK from the voltage-controlled oscillator 10. The programmable frequency divider 20 also receives a signal (division signal) related to a frequency division ratio N of the oscillation clock signal VCO CLK from the determination control circuit DET. Based on the division signal, the programmable frequency divider 20 generates the frequency-divided clock signal DIV CLK obtained by frequency dividing the oscillation clock signal VCO CLK. The programmable frequency divider 20 outputs the frequency-divided clock signal DIV CLK. That is, in the phase-locked loop PLL of the present embodiment, the frequency division ratio (N) of the feedback frequency divider 20 is controllable.

The phase frequency detector 30 is a circuit that compares the phases of the reference clock signal REF CLK and the frequency-divided clock signal DIV CLK. The phase frequency detector 30 detects the difference in phase between the reference clock signal REF CLK and the frequency-divided clock signal DIV CLK, and outputs the detection result as a pulsed signal.

The charge pump 40 converts the pulsed signal output by the phase frequency detector 30 into a voltage level, and outputs the conversion result.

The loop filter 50 is a low-pass filter that functions as a feedback loop filter of the phase-locked loop PLL. The loop filter 50 outputs the control voltage Vc, which is obtained by filtering the output of the charge pump 40. The output voltage Vc from the loop filter 50 is input to the voltage-controlled oscillator 10.

In this way, the phase-locked loop PLL forms a phase control loop in which the phase of the frequency-divided clock signal DIV CLK (obtained by frequency dividing the oscillation clock signal VCO CLK generated by the voltage-controlled oscillator 10) is compared with the phase of the reference clock signal REF CLK. The comparison result is fed back to the phase-locked loop PLL.

The calibration control circuit CAL is a circuit block that adjusts the base oscillation frequency for the oscillation clock signal VCO CLK as generated by the voltage-controlled oscillator 10. The calibration control circuit CAL receives the reference clock signal REF CLK and the frequency-divided clock signal DIV CLK, and generates a calibration code (“CAL CODE”). The calibration control circuit CAL includes a calibration circuit 60 and a code generator 70.

The calibration circuit 60 receives the reference clock signal REF CLK and the frequency-divided clock signal DIV CLK. The calibration circuit 60 compares the frequency of the reference clock signal REF CLK and the frequency of the frequency-divided clock signal DIV CLK to each other. The calibration circuit 60 outputs a signal indicating the comparison result.

The code generator 70 receives the comparison result output by the calibration circuit 60. The code generator 70 generates the calibration code (“CAL CODE”). based on the comparison result. The code generator 70 outputs the generated calibration code.

The voltage-controlled oscillator 10 generates the oscillation clock signal VCO CLK having the base frequency corresponding to the calibration code generated by the code generator 70. The adjustment of the oscillation frequency in accordance with the calibration code is performed, for example, when the oscillation frequency of the oscillation clock signal VCO CLK exceeds a frequency range which is controllable by the voltage-controlled oscillator 10 in accordance with the control voltage Vc.

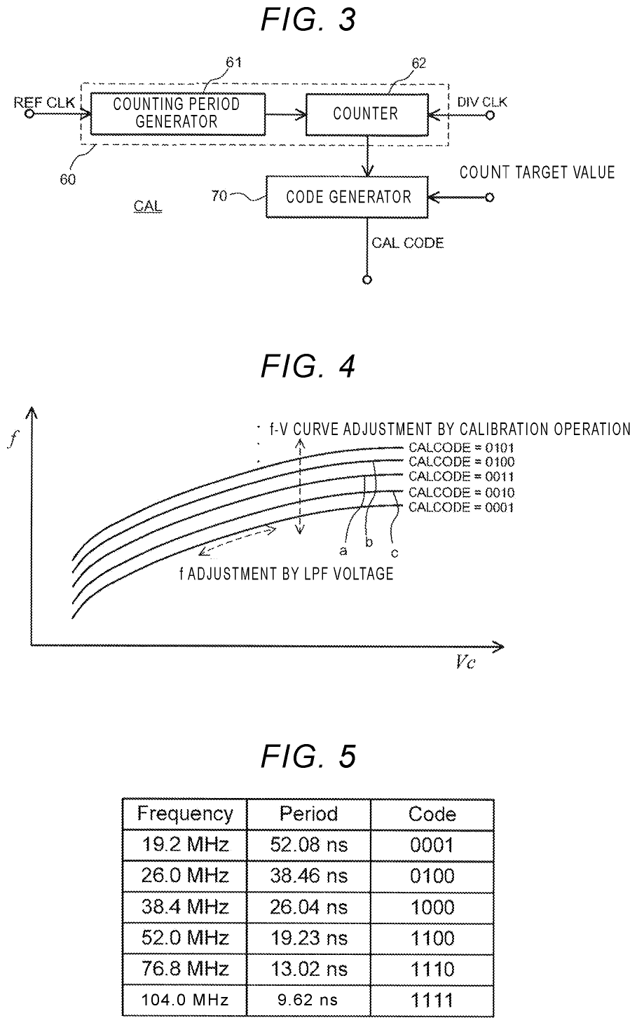

An example of the configuration of the calibration circuit 60 of the calibration control circuit CAL will be described with reference to FIG. 3. As illustrated in FIG. 3, the calibration circuit 60 includes a counting period generator 61 and a counter 62. The counting period generator 61 is a circuit block that generates a timing signal of a certain time interval based on the reference clock signal REF CLK. The timing signal is a signal generated at a time interval corresponding to a particular number of pulses of the reference clock signal REF CLK. The counter 62 counts (as a count value) the number of pulses of the frequency-divided clock signal DIV CLK input during the period based on the timing signal obtained from the counting period generator 61. For example, when the period based on the timing signal is a period corresponding to ten pulses of the reference clock signal REF CLK, the counter 62 counts the number of pulses of the frequency-divided clock signal DIV CLK received in the period. By comparing the number of pulses, the counter 62 can determine which of the reference clock signal REF CLK and the oscillation clock signal VCO CLK has a higher frequency.

Based on the count value counted by the counter 62, the code generator 70 generates the calibration code (“CAL CODE”) for controlling the base oscillation frequency of the voltage-controlled oscillator 10. The count value of the counter 62 is the comparison result of the calibration circuit 60. For example, when the count value received from the counter 62 is smaller than a threshold value, the code generator 70 adds one (1) to the calibration code, and when the count value received from the counter 62 is larger than the threshold value, the code generator 70 subtracts one (1) from the calibration code. The voltage-controlled oscillator 10 changes the base oscillation frequency in accordance with the received calibration code (“CAL CODE”).

In this way, a frequency control loop is formed in which the base frequency of the voltage-controlled oscillator 10 is roughly adjusted in accordance with the calibration code. That is, the control loop by the calibration control circuit CAL is the frequency control loop.

As illustrated in FIG. 2, the determination control circuit DET receives the reference clock signal REF CLK and the frequency-divided clock signal DIV CLK, and outputs the signal related to the frequency division ratio N. The determination control circuit DET is a circuit block that detects the locked state of the operation of the phase-locked loop PLL, and controls the frequency division ratio N to be given to the programmable frequency divider 20. Further, the determination control circuit DET determines whether the calibration code CAL CODE generated by the code generator 70 is in an appropriate range. The description that the operation of the phase-locked loop PLL is locked has the same meaning as the description that the phase-locked loop PLL is locked. The state where the operation of the phase-locked loop PLL is locked refers to a state where the shift in frequency and phase between the reference clock signal REF CLK and the oscillation clock signal VCO CLK is in an allowable range. The expression “being locked” has the same meaning as “being brought into the locked state”.

The determination control circuit DET includes a lock detection circuit 80, a determination circuit 82, a frequency division ratio setting circuit 84, and a code comparison circuit 86. The lock detection circuit 80 is a circuit block that compares the phase of the reference clock signal REF CLK and the phase of the frequency-divided clock signal DIV CLK, and detects whether the operation of the phase-locked loop PLL is locked. The determination control circuit DET outputs a signal indicating the detection result.

The determination circuit 82 is a circuit block that determines whether the operation of the phase-locked loop PLL is locked, based on the output signal of the lock detection circuit 80, and controls the frequency division ratio N to be given to the programmable frequency divider 20 according to the determination result. When it is determined that the operation of the phase-locked loop PLL is not locked based on the output signal of the lock detection circuit 80, the determination circuit 82 changes the frequency division ratio N to be given to the programmable frequency divider 20 in the frequency division ratio setting circuit 84. When it is determined that the operation of the phase-locked loop PLL is locked based on the output signal of the lock detection circuit 80, the determination circuit 82 fixes the frequency division ratio N to be given to the programmable frequency divider 20 in the frequency division ratio setting circuit 84. The determination circuit 82 outputs a setting signal for setting the frequency division ratio N to be given to the programmable frequency divider 20, to the frequency division ratio setting circuit 84. The determination circuit 82 also has a function of checking whether the calibration code (“CAL CODE”) generated by the code generator 70 is in a specified range after it is determined that the operation of the phase-locked loop PLL is locked. When the calibration code is outside the specified range, the determination circuit 82 changes the frequency division ratio N again.

The frequency division ratio setting circuit 84 is a circuit block that sets the frequency division ratio N of the programmable frequency divider 20 based on the setting signal for setting the frequency division ratio N from the determination circuit 82. The frequency division ratio setting circuit 84 can store multiple frequency division ratio values that correspond to particular frequencies of the reference clock signal REF CLK and give a frequency division ratio N among the stored multiple frequency division ratio values to the programmable frequency divider 20.

The code comparison circuit 86 is a circuit block that compares the calibration code (“CAL CODE”) generated by the calibration control circuit CAL with a threshold value code. The code comparison circuit 86 determines whether the calibration code (“CAL CODE”) generated by the calibration control circuit CAL is a value within a specified range.

In this way, the determination control circuit DET controls the frequency division ratio N of the programmable frequency divider 20 based on the locked state of the operation of the phase-locked loop PLL. Further, the determination control circuit DET controls the frequency division ratio N of the programmable frequency divider 20 based on the propriety of the calibration code generated by the code generator 70.

(Calibration Operation of Clock Generator 100)

As described above, the clock generator 100 includes the calibration control circuit CAL, the phase-locked loop PLL, and the determination control circuit DET. The calibration control circuit CAL roughly adjusts the base frequency of the oscillation clock signal VCO CLK generated by the clock generator 100. The phase-locked loop PLL synchronizes the frequency of the oscillation clock signal VCO CLK with the frequency of the reference clock signal REF CLK based on the base frequency adjusted by the operation of the calibration control circuit CAL. When the operation of the phase-locked loop PLL is not locked, the determination control circuit DET controls the frequency division ratio N of the programmable frequency divider 20 so that the phase-locked loop PLL can be brought into the locked state. Hereinafter, the calibration operation of the clock generator 100 will be described with reference to FIGS. 2 to 5.

The calibration control circuit CAL operates when a reference clock signal REF CLK having a new or unknown frequency is supplied, for example, when the electronic device D is connected to an unknown host device H. When such a reference clock signal REF CLK is supplied, the counting period generator 61 of the calibration circuit 60 generates a timing signal for specifying a counting period, based on the frequency of the reference clock signal REF CLK. Based on the timing signal generated by the counting period generator 61, the counter 62 counts the number of pulses of the frequency-divided clock signal DIV CLK obtained by dividing a clock signal generated by the voltage-controlled oscillator 10.

If the count value counted by the counter 62 during the counting period is less than a threshold value, the code generator 70 generates a calibration code (“CAL CODE”) by adding a certain number (e.g., “1”) to a preset initial calibration code CAL CODE. When the count value is smaller than the threshold value, this indicates that the frequency of the frequency-divided clock signal DIV CLK is lower than the frequency of the reference clock signal REF CLK.

On the other hand, if the count value of the counter 62 is larger than the threshold value, the code generator 70 generates a calibration code (“CAL CODE”) by subtracting a certain number (e.g., “1”) from the initial calibration code. When the count value is larger than the threshold value, this indicates that the frequency of the frequency-divided clock signal DIV CLK is higher than the frequency of the reference clock signal REF CLK.

In FIG. 4, the horizontal axis represents values of the control voltage Vc, and the vertical axis represents values of the frequency “f” of the oscillation clock signal VCO CLK. FIG. 4 represents different frequency ranges of the oscillation clock signal VCO CLK in the same range of the control voltage Vc, for multiple calibration codes CAL CODE. For example, as illustrated in FIG. 4, when the initial calibration code is “0011”, and the count value of the counter 62 is less than the threshold value (that is, the frequency of the frequency-divided clock signal DIV CLK is lower than the frequency of the reference clock signal REF CLK), the code generator 70 adds “1” to the calibration code to obtain “0100” as a new calibration code. As a result, the oscillation characteristic of the voltage-controlled oscillator 10 changes from “a” to “b” in FIG. 4, and the oscillation frequency of the oscillation clock signal VCO CLK with respect to the control voltage Vc shifts to a higher level as a whole. If the count value of the counter 62 now substantially matches the threshold value (that is, the frequency of the reference clock signal REF CLK and the frequency of the frequency-divided clock signal DIV CLK substantially match each other), the calibration code is set (adjusted) to “0100”, and the voltage-controlled oscillator 10 generates the oscillation clock signal VCO CLK with the characteristic of “b” in FIG. 4.

If the initial calibration code is “0011”, and the count value of the counter 62 is larger than the threshold value (that is, the frequency of the frequency-divided clock signal DIV CLK is higher than the frequency of the reference clock signal REF CLK), the code generator 70 subtracts “1” from the initial calibration code to obtain “0010” as a new calibration code. As a result, the oscillation characteristic of the voltage-controlled oscillator 10 changes from “a” to “c” in FIG. 4, and the frequency of the oscillation clock signal VCO CLK with respect to the control voltage Vc shifts to a lower level as a whole. If the count value of the counter 62 matches the threshold value (that is, the frequency of the reference clock signal REF CLK and the frequency of the frequency-divided clock signal DIV CLK substantially match each other), the calibration code is set (adjusted) to “0010”, and the voltage-controlled oscillator 10 generates the oscillation clock signal VCO CLK with the characteristic of “c” in FIG. 4.

In an embodiment, the possible frequencies of the reference clock signal REF CLK can be standardized as, for example, 19.2 MHz, 26 MHz, 38.4 MHz, 52 MHz, 76.8 MHz, or 104 MHz. The voltage-controlled oscillator 10 of the electronic device D may set the frequency division ratio N in accordance with a corresponding frequency, thereby generating the oscillation clock signal VCO CLK of the same frequency. Furthermore, in the correspondence table illustrated in FIG. 5, a frequency of the reference clock signal REF CLK (“Frequency” column value), a period corresponding to the frequency (“Period” column value), and a corresponding code (“Code” column value) are associated with each other. The period of the reference clock signal REF CLK may be referred to when the counting period generator 61 generates the timing signal. The corresponding code may be referred to when the code generator 70 sets an initial value of the calibration code in the voltage-controlled oscillator 10.

(Frequency Detecting Operation of Clock Generator 100)

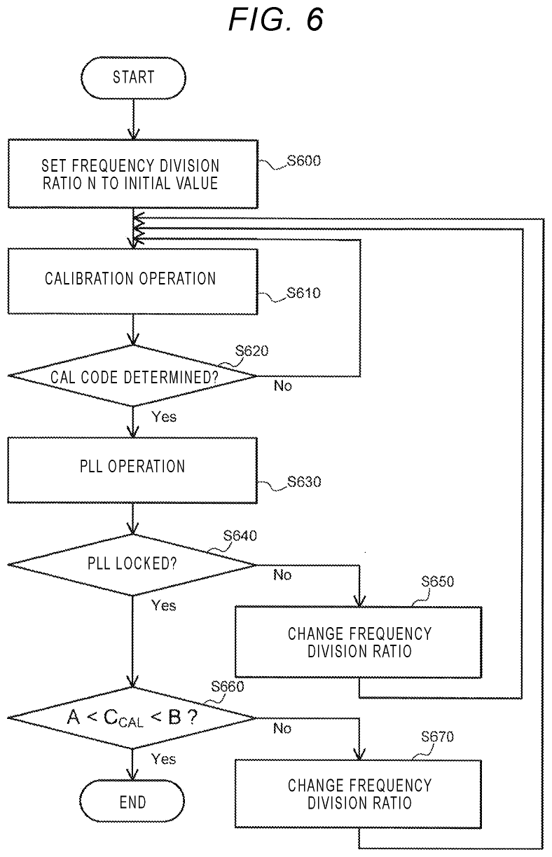

The frequency detecting operation of the clock generator 100 according to an embodiment will be described with reference to FIG. 6. The frequency division ratio setting circuit 84 sets the initial value of the frequency division ratio N to the programmable frequency divider 20 (S600). At this time, the code generator 70 sets the initial value of the calibration code to the voltage-controlled oscillator 10.

When an unknown reference clock signal REF CLK is input to the node CLK IN, the calibration control circuit CAL executes the calibration operation (S610). Here, the calibration circuit 60 compares the unknown reference clock signal REF CLK and the frequency-divided clock signal DIV CLK (obtained by dividing the oscillation clock signal VCO CLK generated by the voltage-controlled oscillator 10), and the code generator 70 increases or decreases the calibration code based on the comparison result of the calibration circuit 60.

The calibration control circuit CAL has a function of discretely adjusting the base oscillation frequency of the voltage-controlled oscillator 10, in other words, the oscillation characteristic (Vc-f), as illustrated in FIG. 4. As a result, even in a situation where the frequency of the reference clock signal REF CLK changes frequently, the frequency locking by the phase-locked loop PLL can be quickly operated. With the nature of the function, the calibration control circuit CAL locks the calibration code (“CAL CODE”) before the phase-locked loop PLL is started.

The calibration control circuit CAL continues to increase or decrease the calibration code until the calibration code is locked/determined (S610; No in S620). When the calibration code is locked/determined (Yes in S620), the code generator 70 gives this finally locked calibration code (“C_{CAL}”) to the voltage-controlled oscillator 10. The voltage-controlled oscillator 10 generates the oscillation clock signal VCO CLK based on this calibration code. The phase-locked loop PLL controls the frequency-divided clock signal DIV CLK to be synchronized with the reference clock signal REF CLK (S630). That is, the phase-locked loop PLL performs a PLL operation.

The operation of the phase-locked loop PLL is to synchronize the frequency-divided clock signal DIV CLK with the reference clock signal REF CLK. The oscillation clock signal VCO CLK generated by the voltage-controlled oscillator 10 is input to the programmable frequency divider 20. The programmable frequency divider 20 sends the frequency-divided clock signal DIV CLK (obtained by dividing the oscillation clock signal VCO CLK using the frequency division ratio N given from the frequency division ratio setting circuit 84) to the phase frequency detector 30. The phase frequency detector 30 compares the phase of the reference clock signal REF CLK and the phase of the frequency-divided clock signal DIV CLK, and sends a pulsed signal corresponding to the phase difference to the charge pump 40. The charge pump 40 converts the received signal into a voltage level. The conversion result is sent to the voltage-controlled oscillator 10 as an output voltage Vc via the loop filter 50. The voltage-controlled oscillator 10 generates the oscillation clock signal VCO CLK of which frequency is controlled by using the output voltage Vc of the loop filter 50 as a control voltage. Through the phase-locked loop, the voltage-controlled oscillator 10 can generate the stable oscillation clock signal VCO CLK in synchronization with the reference clock signal REF CLK.

The lock detection circuit 80 monitors both the reference clock signal REF CLK (input to the phase frequency detector 30) and the frequency-divided clock signal DIV CLK (output by the programmable frequency divider 20). Based on the monitoring result of the lock detection circuit 80, the determination circuit 82 determines whether the operation of the phase-locked loop PLL is locked (S640).

If the operation of the phase-locked loop PLL is not yet locked (No of S640), the frequency division ratio setting circuit 84 changes the frequency division ratio N of the programmable frequency divider 20 from the initial value (S650). When the frequency division ratio N is changed, the frequency of the frequency-divided clock signal DIV CLK also changes. Accordingly, the calibration control circuit CAL starts the calibration operation (S610) again, and once the calibration code is determined (Yes in S620), the phase-locked loop PLL performs the PLL operation (S630). The subsequent operations are performed in the same manner as described above.

When the operation of the phase-locked loop PLL is locked (Yes in S640), the code comparison circuit 86 compares the value of the calibration code (“C_{CAL}”) at the locked time with a specified range having a minimum threshold value A and a maximum threshold value B (S660).

In the determination circuit 82, when the calibration code (“C_{CAL}”) value is less than or equal to the minimum threshold value A or greater than or equal to the maximum threshold value B (No in S660), the frequency division ratio setting circuit 84 changes the frequency division ratio N of the programmable frequency divider 20 again, and sets the now-changed frequency division ratio N in the programmable frequency divider 20 (S670). After the frequency division ratio N is changed, the calibration control circuit CAL starts the calibration operation again (S610), and when the calibration code is determined (Yes in S620), the phase-locked loop PLL performs the PLL operation again (S630). The subsequent operations are performed in the same manner as described above.

In the determination circuit 82, when the calibration code (“C_{CAL}”) exceeds the minimum threshold value A but is less than the maximum threshold value B (Yes in S660), the frequency division ratio setting circuit 84 fixes (sets) the frequency division ratio N to be given to the programmable frequency divider 20. As a result, the frequency of the oscillation clock signal VCO CLK generated by the voltage controlled oscillator 10 is stabilized. Since the frequency division ratio N at this time corresponds to the frequency of the oscillation clock signal VCO CLK generated by the voltage-controlled oscillator 10, the frequency of the reference clock signal REF CLK can be detected based on the value of the frequency division ratio N set by the frequency division ratio setting circuit 84.

(Principle of Frequency Detection by Clock Generator)

If the electronic device D is connected to a host device H that supplies an unknown reference clock signal REF CLK, the frequency of the reference clock signal REF CLK will be unknown at the time the electronic device D is first connected to the host device H. When a signal having an unknown frequency is supplied from a host device H, the clock generator 100 also operates as a frequency detector that detects the unknown frequency. The principle of the frequency detection of the clock generator 100 will be described with reference to FIGS. 2, and 7 to 9. The clock generator 100 detects the frequency in the locking process of the operation of the phase-locked loop PLL.

In some examples, the frequency of the reference clock signal REF CLK matches one of certain possible values for an internal clock signal of the electronic device D. For example, the standard frequencies may be 19.2 MHz, 26 MHz, 38.4 MHz, 52 MHz, 76.8 MHz, and 104 MHz. Considering these examples, the difference between the assumed lowest and highest frequencies is large, and thus, the clock generator 100 controls the base frequency of the voltage-controlled oscillator 10 through the control loop by the calibration control circuit CAL to cover all of the possible standard frequencies.

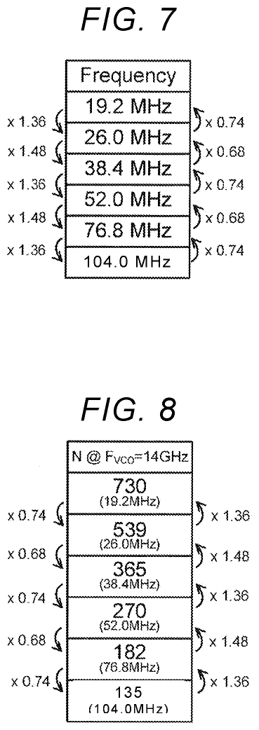

The frequency candidates for the reference clock signal REF CLK are, in this example, a set of frequencies having a certain frequency interval. Thus, the clock generator 100 can discretely change the oscillation frequency of the voltage-controlled oscillator 10 in accordance with the candidate frequencies of the reference clock signal REF CLK. For example, as illustrated in FIG. 7, when the candidate frequencies of the reference clock signal REF CLK are 19.2 MHz, 26 MHz, 38.4 MHz, 52 MHz, 76.8 MHz, and 104 MHz, the difference between adjacent frequencies is about 36% or more when the frequency is swept in the increasing direction, and is about 26% or more when the frequency is swept in the decreasing direction. Normally, it is expected that the range of the oscillation frequency of the voltage-controlled oscillator of an LC-type is around about 20%, and when a reference clock signal REF CLK having a frequency exceeding the range is input to the phase-locked loop PLL in the locked state, the operation of the phase-locked loop PLL cannot be locked. That is, when the frequency interval of two adjacent frequencies is 20% or more, the operation of the phase-locked loop PLL cannot be locked. Thus, when the oscillation frequency of the voltage-controlled oscillator 10 is discretely controlled in accordance with the assumed frequencies of the reference clock signal REF CLK, the frequency of the reference clock signal REF CLK can be obtained by detecting whether the operation of the phase-locked loop PLL can be locked.

As the method of discretely changing the oscillation frequency of the voltage-controlled oscillator 10, the clock generator 100 changes the frequency division ratio N of the programmable frequency divider 20 (which is a frequency division circuit in the loop of the phase-locked loop PLL).

For example, FIG. 8 shows values for the frequency division ratios N required to be used for the candidate frequency values (see FIG. 7) of the reference clock signal REF CLK when the base oscillation frequency of the voltage-controlled oscillator 10 is 14 GHz. Here, the frequency division ratio N is the base oscillation frequency of the voltage-controlled oscillator 10 divided by the reference candidate frequency. As illustrated in FIG. 8, the frequency division ratio setting circuit 84 stores the frequency division ratios N of 730, 539, 365, 270, 182, and 135 in order to support a reference clock signal REF CLK having any of 19.2 MHz, 26 MHz, 38.4 MHz, 52 MHz, 76.8 MHz, or 104 MHz frequency. Then, the frequency division ratio setting circuit 84 selects a frequency division ratio N from this frequency division ratio group, and supplies the selected frequency division ratio N value to the programmable frequency divider 20. As a result, the phase-locked loop PLL can be brought into the locked state after the frequency division ratio N is input.

As illustrated in FIGS. 7 and 8, when the frequency division ratio N at which the operation of the phase-locked loop PLL is locked is determined, the frequency of the reference clock signal REF CLK is also determined at the same time. In the clock generator 100, the frequency of the reference clock signal REF CLK can be acquired by the procedures described above.

Next, with reference to FIGS. 4 and 7 to 9, descriptions will be made related to the significance of the determination of whether the calibration code value is in the specified range after the operation of the phase-locked loop PLL is locked. As illustrated in FIG. 4, the calibration control circuit CAL in the clock generator 100 controls the characteristic of the control voltage Vc given to the voltage-controlled oscillator 10 and the oscillation frequency “f”. However, since the change range of the oscillation frequency of the voltage-controlled oscillator 10 by the control voltage Vc is relatively large, the phase-locked loop PLL can be locked at the frequency of the reference clock signal REF CLK through the control of the control voltage Vc, even though the calibration code might not be at an optimum value.

In consideration of the stability of the system, it is desirable to oscillate the voltage-controlled oscillator 10 in a region where the system operates as stably as possible. Thus, in the clock generator 100, it is checked whether the calibration code is in the range of the expected stable operation after the operation of the phase-locked loop PLL has been locked, and when the calibration code is outside the appropriate range, the frequency division ratio N is changed again, and the calibration operation and the PLL operation are performed. Then, the operation of the phase-locked loop PLL is locked by the frequency division ratio N in which the calibration code falls within the specified range.

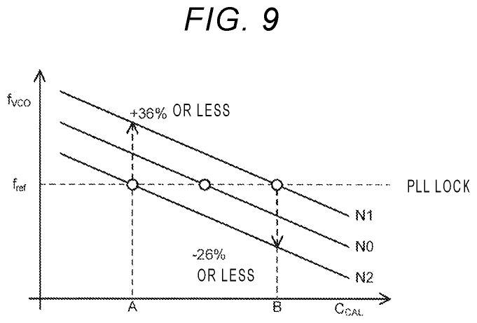

For example, when six standard reference clock signals REF CLK possibilities are assumed, as illustrated in FIG. 7, the operation of the phase-locked loop PLL may be locked with not only a particular locked frequency division ratio NO (see FIG. 9) but also with one of the adjacent frequency division ratios N1 and N2 (see FIG. 9). However, as illustrated in FIG. 9, this locking is implemented at the edge points A and B of the adjacent frequency division ratios N1 and N2 which correspond to the change range of calibration code (“C_{CAL}” value in FIG. 9), and thus, is not desirable from the viewpoint of the system stability.

In the clock generator 100, it is checked whether the calibration code is in the specified range (that is, between A and B in FIG. 9), after the operation of the phase-locked loop PLL is locked. If the calibration code is not in the specified range, the frequency division ratio N value is changed to implement the locking with another frequency division ratio N value.

In the clock generator 100, the frequency of the reference clock signal REF CLK can be detected without increasing the circuit scale. Further, in the clock generator 100, the locking can be determined by sweeping the frequency division ratio of the feedback frequency divider in the phase-locked loop PLL, so that the high accuracy can be achieved without requiring a preliminary test in the initial mounting of the system/device. In the clock generator 100, the frequency division ratio N can be controlled in the two stages of success/failure in the locking of the operation of the phase-locked loop PLL and success/failure in the locking of the calibration control circuit CAL. However, the present disclosure is not limited thereto. The frequency of an unknown reference clock signal REF CLK may be acquired based on the success/failure in the locking of the operation of the phase-locked loop PLL and the frequency division ratio N at that time.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor integrated circuit, comprising:
a calibration control circuit configured to generate a setting value for a frequency of a first clock signal, the setting value based on a frequency of a second clock signal from an external device and a frequency of a third clock signal that is obtained by dividing the first clock signal by a first frequency division ratio;
a phase-locked loop configured to:
generate a control voltage signal based on a difference in phase between the second and third clock signals, and
generate the first clock signal based on the generated control voltage and the setting value; and
a determination control circuit configured to:
determine whether the first and second clock signals are in a locked state, and
update the first frequency division ratio based on whether the first and second clock signals are in the locked state.

2. The semiconductor integrated circuit according to claim 1, wherein the calibration control circuit includes:
a calibration circuit configured to compare the frequency of the second clock signal with the frequency of the third clock signal, and
a code generator configured to generate the setting value corresponding to one of a plurality of particular frequencies based on a result of the comparison.

3. The semiconductor integrated circuit according to claim 2, wherein the phase-locked loop includes an oscillation circuit configured to receive the setting value from the code generator and generate the first clock signal based on the control voltage and the setting value.

4. The semiconductor integrated circuit according to claim 3, wherein the oscillation circuit uses LC resonance to generate the first clock signal.

5. The semiconductor integrated circuit according to claim 1, wherein the determination control circuit includes:
a determination circuit configured to check whether the first and second clock signals are in the locked state, and
a setting circuit configured to change the first frequency division ratio when the first and second signals are not in the locked state and input the changed first frequency division ratio to the phase-locked loop.

6. The semiconductor integrated circuit according to claim 1, wherein
the determination control circuit includes a comparison circuit configured to compare the setting value to a first threshold value and a second threshold value that is larger than the first threshold value, and
the first frequency division ratio is updated when the setting value is less than or equal to the first threshold value or greater than or equal to the second threshold value.

7. The semiconductor integrated circuit according to claim 1, wherein the second clock signal is one of a plurality of predetermined frequencies.

8. The semiconductor integrated circuit according to claim 7, wherein a frequency interval between two of the predetermined frequencies that are adjacent to each other is at least 20% of at least one of the two predetermined frequencies.

9. The semiconductor integrated circuit according to claim 1, further comprising:
an input terminal at which the second clock signal is input, and
an output terminal from which the first clock signal is output.

10. The semiconductor integrated circuit according to claim 9, wherein the second clock signal is a reference clock signal that is input from the external device through the input terminal.

11. An electronic device, comprising:
an interface circuit configured to communicate with an external device; and
a semiconductor integrated circuit including:
a calibration control circuit configured to generate a setting value for a frequency of a first clock signal based on a frequency of a second clock signal that is input from the external device via the interface circuit and a frequency of a third clock signal that is obtained by dividing the first clock signal by a first frequency division ratio,
a phase-locked loop configured to:
generate a control voltage signal based on a difference in phase between the second and third clock signals, and
generate the first clock signal based on the generated control voltage and the setting value, and
a determination control circuit configured to:
determine whether the first and second clock signals are in a locked state, and
update the first frequency division ratio based on whether the first and second clock signals are in the locked state, wherein
the interface circuit uses the first clock signal to communicate with the external device.

12. The electronic device according to claim 11, wherein the calibration control circuit includes:
a calibration circuit configured to compare the frequency of the second clock signal with the frequency of the third clock signal, and
a code generator configured to generate the setting value corresponding to one of a plurality of particular frequencies based on a result of the comparison.

13. The electronic device according to claim 12, wherein the phase-locked loop includes an oscillation circuit configured to receive the setting value from the code generator and generate the first clock signal based on the control voltage and the setting value.

14. The electronic device according to claim 13, wherein the oscillation circuit uses LC resonance to generate the first clock signal.

15. The electronic device according to claim 11, wherein the determination control circuit includes:
a determination circuit configured to check whether the first and second clock signals are in the locked state, and
a setting circuit configured to change the first frequency division ratio when the first and second signals are not in the locked state and input the changed first frequency division ratio to the phase-locked loop.

16. The electronic device according to claim 11, wherein
the determination control circuit includes a comparison circuit configured to compare the setting value to a first threshold value and a second threshold value that is larger than the first threshold value, and
the first frequency division ratio is updated when the setting value is less than or equal to the first threshold value or greater than or equal to the second threshold value.

17. The electronic device according to claim 11, wherein the second clock signal is one of a plurality of predetermined frequencies.

18. The electronic device according to claim 17, wherein a frequency interval between two of the predetermined frequencies that are adjacent to each other is at least 20% of at least one of the two predetermined frequencies.

19. The electronic device according to claim 11, further comprising:
a memory that stores data transmitted from the host device via the interface circuit.

20. A frequency detecting method for a semiconductor integrated circuit, the method comprising:
generating a setting value for a frequency of a first clock signal that is internally generated in an integrated circuit based on a frequency of a second clock signal that is input to the integrated circuit from an external device and a frequency of a third clock signal that is obtained by dividing the first clock signal by a first frequency division ratio;
generating a control voltage signal based on a difference in phase between the second and third clock signals;
generating the first clock signal based on the generated control voltage and the setting value;
determining whether the first and second clock signals are in a locked state; and
updating the first frequency division ratio based on whether the first and second clock signals are in the locked state.
